(19) United States
(12) Patent Application Publication
(10) Pub. No.: US 2007/0089782 A1
(43) Pub. Date: Apr. 26, 2007

(54) Spherical or grain-shaped semiconductor element for use in solar cells and method for producing the same; method for producing a solar cell comprising said semiconductor element and solar cell

(75) Inventors: Jaques Scheuten, Maaseik (BE); Volker Geyer, Lamertzweg (DE); Patrick Kaas, De Stoutheuvel (NL)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Scheuten Glasgroep, Venlo (NL)

(21) Appl. No.: 10/574,633

(22) PCT Filed: Sep. 22, 2004
(86) PCT No.: PCT/EP04/10615

§ 371 Date: Nov. 13, 2006

(30) Foreign Application Priority Data
Oct. 2, 2003 (EP) 03022301.0

(51) Int. Cl. H01L 31/00

(52) U.S. Cl. 136/262; 136/264

(57) ABSTRACT

A spherical or grain-shaped semiconductor element for use in solar cells and to a method for producing the semiconductor element. Also disclosed is a solar cell including an integrated spherical semiconductor element, a method for producing the solar cell, and a photovoltaic module including at least one solar cell. The semiconductor element includes a back contact layer and a I-III-VI compound semiconductor deposited on a spherical or grain-shaped substrate core. The I-III-VI compound semiconductor is produced by applying precursor layers and subsequent selenization or sulfurization. For producing a solar cell, a plurality of the inventive semiconductor elements is introduced into a substrate layer from which they project on at least one face thereof. The substrate layer is striped on one side, thereby exposing the back contact layer of most of the semiconductor elements. This back contact layer can be contacted to the back contact of the solar cell while a front contact is provided on the side of the semiconductor elements that was not stripped.

The invention relates to a spherical or grain-shaped semiconductor element for use in solar cells and to a method for the production of said semiconductor element.

The invention also relates to a solar cell having integrated spherical or grain-shaped semiconductor elements and to a method for the production of said solar cell.

The invention also relates to a photovoltaic module having at least one solar cell having integrated semiconductor elements.

In photovoltaic cells, the photovoltaic effect is utilized in order to convert solar radiation energy into electric energy. Solar cells used for this purpose are made primarily of planar wafers in which a conventional p-n junction is realized. In order to produce a p-n junction and other function layers, in addition to applying and processing individual continuous layer surfaces, it has proven to be practical to apply semiconductor material in spherical or grain-shaped form since this entails a number of advantages.

For example, when it comes to producing electronic devices, it has long since been a known procedure to incorporate electronically active material as particles into a layer in order to increase the activity of the material. This is described, for example, in U.S. Pat. No. 3,736,476. In an embodiment disclosed therein, a core and a layer surrounding the core are configured in such a way as to create a p-n junction. Several of the particles produced in this manner are incorporated into an insulating support layer in such a way that they protrude from the surface on both sides of the layer and can be contacted by further layers.

Moreover, German Preliminary Published Application DE 100 52 914 A1 describes a semiconductor device that is made up of a layer structure consisting of an electrically conductive support layer, an insulating layer, semiconductor particles and an electrically conductive cover layer, whereby the semiconductor particles are incorporated into the insulating layer and they touch the support layer that is underneath it as well as the cover layer that is above it. The semiconductor particles can consist, for example, of silicon or I-III-VI semiconductor particles that are coated with II-VI compounds.

The background for the use of I-III-VI compound semiconductors such as copper indium diselenide, copper indium sulfide, copper indium gallium sulfide and copper indium gallium diselenide can be found, for example, in U.S. Pat. No. 4,335,266 (Mickelsen et al.) and U.S. Pat. No. 4,581,108 (Kapur) in which this type of semiconductor and methods for their production are described in depth I-III-VI compound semiconductors are also referred to below as chalcopyrites or CIS or CIGS (Copper Indium Gallium diSelenide) semiconductors.

It is also a known procedure to configure independent spherical semiconductor elements that constitute complete semiconductors, including the requisite electrodes. For example, European patent application EP 0 940 860 A1 describes using a spherical core to make a spherical semiconductor element by means of masking, etching steps and the application of various material layers. Such semiconductor elements can be used as solar cells if the p-n junction is selected in such a way that it can convert incident light into energy. If the p-n junction is configured in such a way that it can convert an applied voltage into light, then the semiconductor element can be employed as a light-emitting element.

In view of the wide array of envisaged areas of application for such semiconductor elements, the elements have to be completely independent components with electrode connections that can be installed in other applications. This calls for a high complexity of the semiconductor elements and of the requisite production processes. Due to the small dimensions amounting to a few millimeters on the part of the spherical shapes employed, the production of the spherical elements with all of the function layers and processing steps is very expensive.

The objective of the invention is to provide a semiconductor element having a high activity that is suitable for flexible use in various solar cells.

The objective of the invention is also to provide an efficient method for the production of a semiconductor element for use in solar cells.

Another objective of the invention is to provide a method for incorporating a semiconductor element into a solar cell.

It is likewise the objective of the invention to provide a solar cell having integrated semiconductor elements and a photovoltaic module having at least one solar cell.

According to the invention, this objective is achieved by the features of the main claims 1, 21, 37 and 45. Advantageous refinements of the invention can be gleaned from the subordinate claims.

According to the invention, the objective is achieved by a spherical or grain-shaped semiconductor element for use in a solar cell. The method for the production of such a semiconductor element is characterized by the application of a conductive back contact layer onto a spherical or grain-shaped substrate core, by the application of a first precursor layer made of copper or copper gallium, by the application of a second precursor layer made of indium and by the reaction of the precursor layers with sulfur and/or selenium to form a I-III-VI compound semiconductor.

The reaction of the precursor layers takes place in the presence of selenium and/or sulfur and is referred to as selenization or sulfurization. These processes can be carried out in various ways with parameters that are coordinated with the given process. These parameters include, for example, temperature, time, atmosphere and pressure. The selenization or sulfurization can take place, for example, in the vapor, melts or salt melts of the reaction element in question or in the salt melts with admixtures of sulfur and/or selenium. The elements sulfur and selenium can be used simultaneously as well as consecutively for reaction purposes. In an especially preferred embodiment of the invention, the reaction takes place in hydrogen compounds of sulfur or selenium.

In order to obtain a I-III-VI compound semiconductor layer with defined properties, certain parameters of the precursor layers have to be set. Aside from the composition, these parameters also include the thicknesses of the individual layers. Here, due to the spherical shape and the consequently varying diameter, if applicable, layer thickness ratios should be selected that are different from those of prior-art methods in order to create planar I-III-VI compound semiconductors.

In an especially preferred embodiment of the invention, the substrate core that is to be coated consists of glass, especially soda-lime glass, since this is a good source of sodium for the layer structuring. The main constituent of the conductive back contact layer is preferably molybdenum. In an especially preferred embodiment of the invention, the back contact layer contains up to 20% by weight of gallium in order to improve the adhesion. The individual layers can each be applied by means of physical vapor deposition (PVD) methods such as sputtering or evaporation coating or else by means of chemical vapor deposition (CVD) methods.

The precursor layers can be alloyed at temperatures of typically >220° C. [>428° F.] prior to the reaction to form a I-III-VI compound semiconductor. Additional processing steps or coatings can be implemented after the reaction of the precursor layer system to form a I-III-VI compound semiconductor. These include, for example, a treatment with a KCN solution (e.g. 10% KCN solution in alkaline 0.5% KOH solution) in order to remove detrimental surface layers such as copper sulfur compounds. Moreover, a buffer layer, a high-resistance and a low-resistance ZnO layer can be deposited.

Consequently, the spherical or grain-shaped semiconductor element according to the invention for use in solar cells has a spherical or grain-shaped substrate core that is coated at least with one back contact layer and with one I-III-VI compound semiconductor. The substrate core preferably consists of glass, metal or ceramics and the diameter of the substrate core is in the order of magnitude of 0.05 mm to 1 mm. A diameter of 0.2 mm has proven to be especially advantageous. The thickness of the back contact layer is in the order of magnitude of 0.1 μm to 1 μm. The I-III-VI compound semiconductor layer consists, for example, of copper indium diselenide, copper indium sulfide, copper indium gallium sulfide or copper indium gallium diselenide. The thickness of this layer is in the order of magnitude of 1 μm to 3 μm.

Spherical or grain-shaped semiconductor elements produced with the described process steps constitute elements for further use in the production of solar cells. The advantages of such semiconductor elements for use in solar cells lie, for example, in the fact that a I-III-VI compound semiconductor can be produced that is suitable for incorporation into different kinds of solar cells. This includes, among other things, solar cells of different dimensions. Flat solar cells with I-III-VI compound semiconductors are conventionally produced in reactors that have to be precisely adapted to the size of the envisaged solar cells in order to comply with certain parameters. As a result, large-surface solar cell structures also call for correspondingly large reactors in which, for instance, large total masses have to be heated up and cooled off again during the reaction under the influence of heat. This entails a high energy demand. In contrast, the production of spherical or grain-shaped semiconductor elements for subsequent incorporation into solar cells requires far less energy since relatively small volumes have to be reacted in the reactors in question.

Another advantage is the higher flexibility during the production process. If, for example, with conventional solar cell surfaces, larger or smaller structures are to be reacted in a reactor, an appropriate new reactor has to be provided in order to be able to precisely set the requisite parameters. This is very cost-intensive. The production of such conventional thin-layer modules is thus limited by the apparatuses employed for manufacturing the semiconductor layer. In contrast, in the production of the spherical semiconductor elements according to the invention, an existing reactor can be augmented by additional reactors in order to produce the necessary quantity of elements. Hence, this greatly simplifies the later production of solar cells for which no reactor is needed but rather only systems for applying additional layers.

Moreover, thanks to the spherical shape, practical layer systems can be achieved that might not be obtainable with flat semiconductor structures. For example, the required thickness of the deposited layers is less. As a result, for example, a back contact layer made of molybdenum and gallium can be used without the resistance of the layer becoming too great, which is the case with flat structures.

The method according to the invention for the production of a solar cell having integrated spherical or grain-shaped semiconductor elements is used to subsequently incorporate semiconductor elements into a solar cell. The method provides for incorporating spherical semiconductor elements into an insulating support layer, whereby the semiconductor elements protrude from the surface of the support layer on at least one side of the support layer, and the spherical or grain-shaped semiconductor elements each consist of a substrate core that is coated at least with one conductive back contact layer and with one I-III-VI compound semiconductor layer. Parts of the semiconductor elements are removed on one side of the support layer so that preferably a surface of the back contact layer of several elements is exposed. Subsequently, a back contact layer can be applied onto this side of the support layer, said back contact layer being in contact with the free back contact layer surfaces of the semiconductor elements. A front contact layer is applied onto the other side of the support layer. Other function layers can be applied in addition to the front contact layer and the back contact layer.

In an especially preferred embodiment of the invention, the semiconductor elements are applied onto the support layer by means of scattering, dusting and/or printing and they are subsequently pressed into the support layer so that they become embedded to a certain extent in the support layer. If the support layer is a thermoplastic film that is laid onto a soft base, the semiconductor elements can be pressed, for example, so deeply into the layer that they penetrate into the soft base and thus protrude on both sides of the support layer.

The support layer can also be configured as a matrix with recesses into which the semiconductor elements are incorporated and, if necessary, attached. This can be done, for instance, by means of a heating and/or pressing procedure.

When parts of the semiconductor elements are removed, part of the support layer can also be removed along with it. The removal can be done, for example, by grinding, polishing, etching, thermal energy input or by photolithographic processes, whereas the back contact layer and the front contact layer can each be deposited by PVD or CVD methods. If, for example, conductive polymers are used as the back contact layer or front contact layer, methods such as brushing on or spraying on have proven to be advantageous.

Thus, the solar cell according to the invention having integrated spherical or grain-shaped semiconductor elements has an insulating support layer into which the semiconductor elements are incorporated, whereby the semiconductor elements protrude from the layer on at least one side of the support layer. The solar cell also has a front contact layer on one side and a back contact layer on the other side. On the side of the back contact layer, several semiconductor elements have a surface that is free of I-III-VI compound semiconductors and that thus frees the back contact layer of the semiconductor element. These surfaces are in direct contact with the back contact layer of the solar cell.

In an especially preferred embodiment of the invention, the support layer consists of an insulating material such as, for example, a polymer. The spherical semiconductor elements were preferably produced by means of the method according to the invention and the front contact layer consists, for example, of a transparent conductive oxide (TCO). The back contact layer consists of a conductive material such as a metal, a TCO or a polymer having conductive particles. The solar cell can have other function layers in addition to the front contact layer and the back contact layer.

Once all of the process steps have been completed, a solar cell having integrated semiconductor elements has been made that entails a number of advantages, especially in comparison to planar semiconductor structures. The essential advantage—in addition to the simplified production—lies in the curved surfaces of the semiconductor elements which can be struck by incident light, irrespective of the incidence direction. Thus, even diffuse light can be used more efficiently in order to generate electricity.

Further advantages, special features and advantageous embodiments of the invention can be gleaned from the subordinate claims and from the presentation below of preferred embodiments making reference to the figures.

The figures show the following:

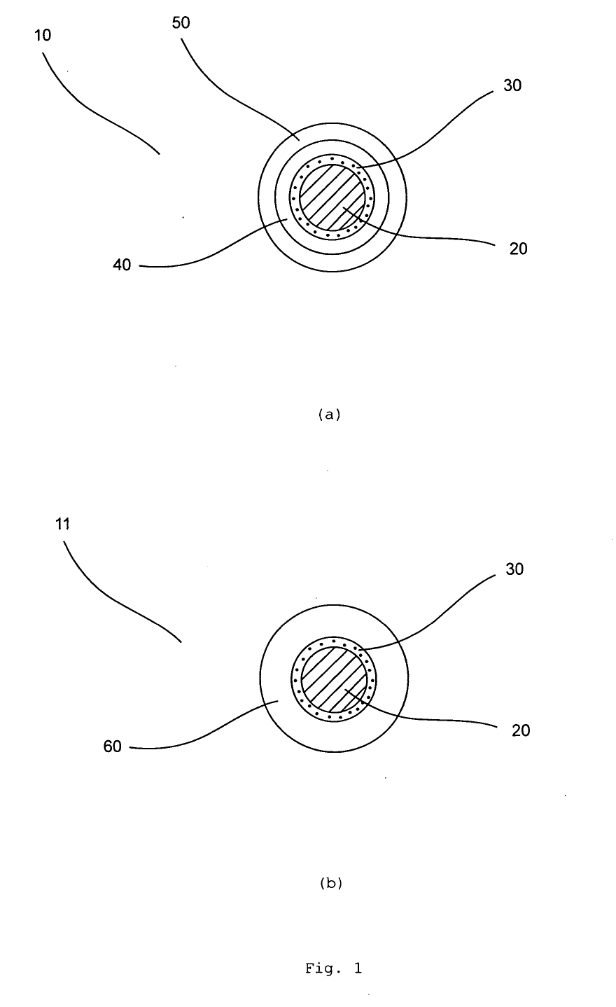

FIG. 1 in illustration (a), an especially preferred embodiment of a layer structure for the production of a spherical semiconductor element and in illustration (b), a semiconductor element produced by means of the method according to the invention; and

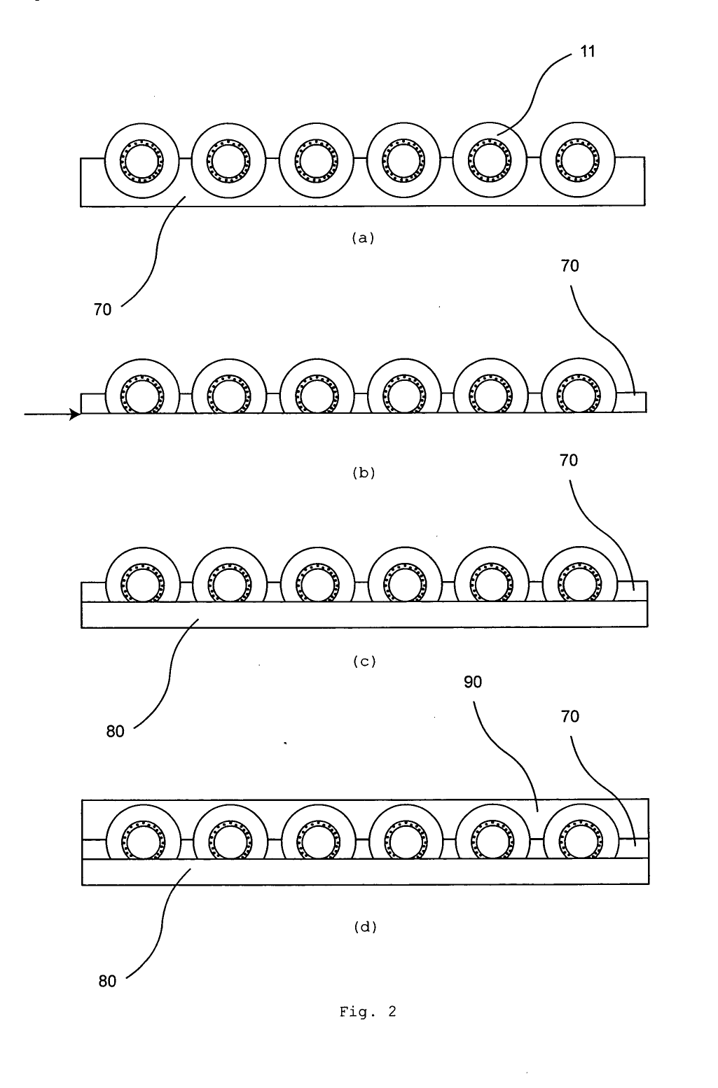

FIG. 2 in illustrations (a) to (d), the process steps according to the invention during the incorporation of a spherical semiconductor element into a solar cell.

FIG. 1, illustration (a), shows an especially preferred embodiment of a layer structure 10 for the production of a spherical or grain-shaped semiconductor element 11. The layer structure 10 can also be seen as the precursor layer structure for the later reaction to form a I-III-VI compound semiconductor. In the first step of the method according to the invention for the production of a spherical semiconductor element 11, a spherical substrate core 20 is coated with a back contact 30. The spherical substrate preferably consists of glass, but it can also be made of other materials such as metals or ceramics. When glass is employed, for example, soda-lime glass can be used, which is a good source of sodium for the later layer structuring. Other glass compositions can also be used.

The substrate is essentially spherical, but the shape can also diverge from a pure spherical shape. Depending on the production process, the resultant spheres can also be designated as being grain-shaped. Hollow bodies made of the above-mentioned materials can also be used. The diameter of the spheres is in the order of magnitude of 0.5 mm to 1 mm, a diameter of approximately 0.2 mm preferably being selected.

The back contact 30 is applied onto the spherical substrate in such a way that the entire surface of the sphere is coated. The material for the back contact is preferably molybdenum, but other suitable conductive materials such as, for instance, tungsten or vanadium can also be used.

The semiconductor core 20 can be coated by means of PVD methods such as sputtering or evaporation coating. CVD methods can also be used; in this context, it must be pointed out that sputtering a large number of small substrate spheres is a very time-consuming process that, in view of the attainable throughput rate, is less suitable than other methods. The thickness of the back contact layer is in the order of magnitude of 0.1 μm to 1 μm.

In order to improve the adhesion of subsequent layers to the back contact layer, a gallium layer can be applied onto the molybdenum layer. In an especially preferred embodiment of the invention, the gallium is incorporated into the molybdenum layer in order to increase the adhesion. This can involve a gallium content of up to 20% by weight. In actual practice, this approach is normally avoided for flat solar cells since it increases the resistance of the back contact in a detrimental manner. However, a gallium-molybdenum layer has proven to be advantageous for the production of the semiconductor elements according to the invention, since thinner layers can be achieved than with flat semiconductors and their greater resistance does not entail any serious drawbacks.

According to the invention, a I-III-VI compound semiconductor is selected as the semiconductor compound. These semiconductors, which are also referred to as chalcopyrites, also include, for example, copper indium diselenide, copper indium sulfide, copper indium gallium sulfide and copper indium gallium diselenide.

In order to produce such a CuGa/InS/Se₂ layer on the substrate, first of all, precursor layers made of copper, gallium and/or indium are applied and these are reacted in a subsequent selenization or sulfurization process to form the envisaged semiconductors. The precursor layers can be applied with the same methods as the back contact so that here, too, PVD methods such as sputtering and evaporation coating or CVD methods can be employed. As the first precursor layer 40, in an especially preferred embodiment of the invention, the spherical substrate is coated with copper. In order to improve the adhesion between this first layer and the back contact, a thin copper-gallium layer can be applied ahead of time as an adhesive.

In a first embodiment of the invention, a second precursor layer 50 in the form of indium is deposited onto the copper layer. An alternating application of Cu/In layer packets (e.g. Cu/In/Cu/In) is likewise possible. The Cu/In layers are subsequently sulfurized with sulfur to form CuInS and a so-called CIS layer is formed. The CIS layer 60 resulting from the precursors and the sulfurization process is shown on the semiconductor element 11 in illustration (b). The precursor layer system consisting of copper and indium can optionally be alloyed at an elevated temperature of typically T>220° C. [428° F.] prior to the sulfurization, which is advantageous for the adhesion and the later reaction with selenium and/or sulfur. This step, however, is not absolutely necessary.

The layer thicknesses of the Cu and In layers are determined by the envisaged layer thickness of the CIS semiconductor. Preferably, the thickness of the CIS layer 60 is in the order of magnitude of 1 μm to 3 μm. Moreover, it has proven to be advantageous for the atomic ratio of Cu to In to be in the order of magnitude of 1 to 2. Special preference is given to atomic ratios of copper to indium of between 1.2 and 1.8.

In a second embodiment of the invention, a copper layer or a copper-gallium layer is applied onto the back contact layer 30 as a first precursor layer 40. This first precursor layer is, in turn, followed by a second precursor 50 in the form of an indium layer, whereby the two layers are subsequently selenized into CuIn/GaSe₂ and form a CIGS layer. The copper-indium/gallium layer system here can also optionally be alloyed at an elevated temperature of typically T>220° C. [428° F.].

In this embodiment, the layer thicknesses are likewise dependent on the envisaged atomic ratio Cu/(In+Ga) after the selenization. It has proven to be advantageous for this ratio to be <1. The layer thickness of the CIGS layer after the selenization is preferably in the order of magnitude of 1 μm to 3 μm. It has turned out that the copper content of the finished CIGS layer can be set smaller than the stoichiometrically necessary value.

The spheres coated with the precursors can be reacted by means of selenization with selenium and/or by means of sulfurization with sulfur. Various methods can be used for this purpose. In an especially preferred embodiment of the invention, the spheres are reacted in a vacuum or at atmospheric pressure with a vapor of the element in question (Se and/or S). This reaction takes place employing certain parameters such as, for instance, temperature, time, process duration, pressure and partial pressure. The reaction can also take place in a melt made up of the elements. Another possibility for the reaction is the salt melt containing S and/or Se.

In another embodiment of the invention, the spheres are reacted to form hydrogen compounds of sulfur and/or of selenium. This can take place, for example, at atmospheric pressure or at a pressure that is less than atmospheric pressure. Sulfur as well as selenium can be used consecutively or simultaneously during the reaction.

In an especially preferred embodiment of the invention, the next process step after the reaction of the spheres is to remove surface layers that have a detrimental effect. These can be, for example, CuS compounds that were formed during the reaction process. One way to remove such layers is through a treatment with a KCN solution. If a sulfurization was carried out, this treatment step is necessary, whereas it can be considered to be optional after selenization.

In a preferred embodiment, the next step is to deposit a buffer layer onto the CIS or CIGS semiconductor. For example, CdS, ZnS, ZnSe, ZnO or CdZnS can be used as the layer materials. Other possible materials are In-Se compounds or In-S compounds. These buffer layers can be deposited by means of coating methods such as CVD, PVD, or by wet-chemical (chemical bath deposition) methods or other suitable methods. The deposition by means of chemical bath deposition has proven to be especially advantageous. The thickness of the buffer layer is preferably in the order of magnitude of 10 nm to 200 nm.

In another especially preferred embodiment of the invention, the next step is to deposit high-resistance ZnO (i-ZnO) onto the layer structure. The deposition of this layer can be carried out with methods such as PVD (reactive or ceramic), CVD or chemical bath deposition. The thickness of the layer is preferably in the order of magnitude of 10 nm to 100 nm.

After the deposition of high-resistance ZnO (approx. 50 nm), in an especially preferred embodiment of the invention, another layer of low-resistance ZnO (ZnO:Al) is deposited. Here, the same deposition methods can be used as those employed for high-resistance ZnO. The thickness of this layer (TCO) is in the order of magnitude of 0.1 μm to 2 μm.

Semiconductor elements produced with the described process steps are elements for further use in the production of solar cells. The semiconductor elements according to the invention can be subsequently incorporated in various ways into solar cells. For example, in another aspect of the invention, the spherical semiconductor elements are embedded in a solar cell as is shown in illustrations (a) to (d) of FIG. 2.

Illustration (a) of FIG. 2 shows the incorporation of the semiconductor elements 11 into an insulating support layer 70. Here, it has proven to be advantageous to use a flexible film as the support layer. The support layer preferably consists of a thermoplastic polymer which can be, for instance, a polymer from the group of the polycarbonates or polyesters. Pre-polymerized resins from the group of the epoxides, polyurethanes, polyacrylics and/or polyimides can be used. Moreover, a liquid polymer can be used into which the spheres are pressed and which subsequently hardens.

The semiconductor elements 11 are preferably incorporated into the support layer 70 in such a way that they protrude from the surface of the layer on at least one side of the support layer. For this purpose, the particles can be applied, for example, by means of scattering, dusting and/or printing, after which they are pressed in. In order to press the bodies into the support layer, the latter can, for instance, be heated up.

In another embodiment of the invention, the particles are incorporated into a prepared matrix of a support layer having recesses into which the particles are incorporated. In order to attach the bodies to the support layer, a heating and/or pressing procedure can be carried out.

If the semiconductor elements are supposed to protrude on both sides of the support layer, the support layer can be situated on a flexible base when the elements are incorporated, so that the semiconductor elements can be pressed so far into the support layer that parts of them emerge from the bottom of the support layer.

In an especially preferred embodiment of the invention, the next step is to remove parts of the semiconductor elements on one side of the support layer. Parts of the support layer can also be removed in this process. This is shown in the illustration (b) of FIG. 2 by an arrow. Here, the support layer 70 is preferably removed down to a layer thickness at which parts of the incorporated bodies are also removed. In the embodiment shown, the removal extends all the way to the back contact layer 30 of the semiconductor element 11 as shown by a dotted line. If the semiconductor elements are incorporated into the support layer in such a way that they protrude from both sides of the layer, it is also possible to process the semiconductor elements on one side without additional removal of the support layer so that, after the removal procedure, the semiconductor elements either protrude further from the support layer or are flush with it.

The removal of the semiconductor elements or of the support layer can also be carried out at different points in time before the application of a later back contact 80 on this side. The removal of the semiconductor elements and/or of the support layer can be done by mechanical procedures such as grinding or polishing, etching, thermal energy input such as, for instance, using a laser or radiation or else by means of photolithographic processes.

In another process step, a conductive back contact layer 80 is applied onto the side on which the semiconductor elements had been removed. Examples of conductive material for this back contact include substances from various classes of polymers. Especially well-suited materials are epoxy resins, polyurethanes and/or polyimides that have been provided with suitable conductive particles such as carbon, indium, nickel, molybdenum, iron, nickel chromium, silver, aluminum and/or the corresponding alloys or oxides. Another possibility comprises intrinsic conductive polymers. These include, for example, polymers from the group of the PANis. Other materials that can be employed are TCOs or suitable metals. In the case of TCOs and metals, the back contact can be applied with PVD or CVD methods.

In another process step, a conductive front contact layer 90 is applied onto the side of the support layer on which no semiconductor elements have been removed. This can also be carried out with methods such as PVD or CVD. Various transparent conductive oxides (TCOs) can be used as the conductive material of the front contact.

Other function layers can be deposited before or after the deposition of a front contact and a back contact. The selection of the other function layers depends especially on the semiconductor elements employed. Function layers such as, for example, buffer layers that have already been deposited onto the semiconductor elements do not necessarily have to be deposited any more for the production of the solar cell having integrated semiconductor elements. All of the required deposition and processing steps yield a solar cell from which a photovoltaic module can be made. One or more of the solar cells can be connected in series, for example, and joined to form a module at which the generated current is tapped.

### LIST OF REFERENCE NUMERALS

10 layer structure, precursor layer structure
11 semiconductor element
20 substrate, substrate core
30 back contact layer of a semiconductor element
40 first precursor layer
50 second precursor layer
60 I-III-VI compound semiconductor, CIS or CIGS layer
70 support layer, insulating
80 back contact layer of a solar cell
90 front contact layer of a solar cell

1. A method for producing a spherical or grain-shaped semiconductor element for use in a solar cell, comprising the steps of:
applying a conductive back contact layer onto a spherical or grain-shaped substrate core;
applying a first precursor layer comprising copper or copper gallium;
applying a second precursor layer comprising indium; and
reacting the precursor layers with sulfur and/or selenium to form a I-III-VI compound semiconductor, by carrying out the reaction of the layer structure in a melt of the reaction element sulfur or selenium, or carrying out the reaction of the layer structure in hydrogen compounds of the reaction element sulfur or selenium, carrying out the reaction in hydrogen compounds at or below atmospheric pressure.

2. The method according to claim 1, wherein the main constituent of the conductive back contact layer is molybdenum.

3. The method according to claim 2, wherein the conductive back contact layer contains up to 20% by weight of gallium in order to improve adhesion.

4. The method according to claim 1, comprising applying each of the layers by a PVD or CVD method.

5. The method according to one claim 1, comprising alloys on a layer structure comprising precursor layers at a temperature of T>220° C. [>428° F.] prior to the reaction to form a I-III-VI compound semiconductor.

6. The method according to claim 1, comprising carrying out a treatment with a KCN solution after reatcing the layer structure to form a I-III-VI compound semiconductor.

7. The method according to claim 1, comprising depositing a buffer layer after reacting the layer structure to form a I-III-VI compound semiconductor.

8. The method according to claim 1, comprising depositing a high-resistance ZnO layer and a low-resistance ZnO layer after reacting the layer structure to form a I-III-VI compound semiconductor.

9. The method according to claim 7, comprising depositing the buffer layer and/or the high-resistance and the low-resistance layers by a PVD or CVD method.

10. A spherical or grain-shaped semiconductor element for use in solar cells, wherein the semiconductor element has a spherical or grain-shaped substrate core that comprising soda-lime glass and is coated at least with one back contact layer comprising molybdenum and one I-III-VI compound semiconductor.

11. The semiconductor element according to claim 10, wherein the diameter of the substrate core is in the order of magnitude of 0.1 mm to 1 mm.

12. The semiconductor element according to claim 10, wherein the thickness of the back contact layer is in the order of magnitude of 0.1 μm to 1 μm.

13. The semiconductor element according to claim 10, wherein the I-III-VI compound semiconductor layer comprising a compound selected from the group consisting of copper indium sulfides, copper indium diselenides, copper indium gallium sulfides, and copper indium gallium diselenides.

14. The semiconductor element according to claim 10, wherein the thickness of the I-III-VI compound semiconductor layer is in the order of magnitude of 1 μm to 3 μm.

15. The semiconductor element according to claim 10, wherein the semiconductor element has a buffer layer above the I-III-VI compound semiconductor layer.

16. The semiconductor element according to claim 15, wherein the buffer layer comprises a material selected from the group consisting of CdS, ZnS, ZnSe, ZnO, indium selenium compounds or indium sulfur compounds.

17. The semiconductor element according to claim 15, wherein the thickness of the buffer layer is in the order of magnitude of 20 nm to 200 nm.

18. The semiconductor element according to claim 10, wherein the semiconductor element has a high-resistance and a low-resistance ZnO layer above the I-III-VI compound semiconductor layer.

19. The semiconductor element according to claim 18, wherein the thickness of the high-resistance layer is in the order of magnitude of 10 nm to 100 nm, which the thickness of the low-resistance ZnO layer is in the order of magnitude of 0.1 μm to 2 μm.

20. The semiconductor element according to claim 10, wherein the semiconductor element is produced by a method according to claim 1.

21. A method for producing a solar cell having integrated spherical or grain-shaped semiconductor elements, comprising the steps of:
incorporating several spherical or grain-shaped semiconductor elements into an insulating support layer, wherein the semiconductor elements protrude from the surface of the support layer on at least one side of the support layer, and the semiconductor elements each comprise a spherical or grain-shaped substrate core that is coated at least with one conductive back contact layer and with one I-III-VI compound semiconductor layer;
removing parts of the semiconductor elements on one side of the support layer so that a surface of the conductive back contact layer of the semiconductor elements is exposed;
applying a back contact layer onto a side of the support layer on which parts of the semiconductor elements have been removed; and
applying a front contact layer onto the side of the support layer on which no semiconductor elements have been removed.

22. The method according to claim 21, comprising, in addition to parts of the semiconductor elements, removing part of the support layer.

23. The method according to claim 21, comprising applying the semiconductor elements onto the support layer by scattering, dusting and/or printing and subsequently incorporated the semiconductor elements into the support layer.

24. The method according to claim 21, comprising configuring the support layer as a matrix with recesses into which the semiconductor elements are incorporated.

25. The method according to claim 21, comprising incorporating the semiconductor elements into the support layer by a heating and/or pressing procedure.

26. The method according to claim 21, comprising removing the semiconductor elements and/or the support layer by grinding, polishing, etching, thermal energy input or a photolithographic process.

27. The method according to claim 21, comprising depositing the back contact layer and/or the front contact layer by a PVD or CVD method or by another method adapted to the material of the layer in question.

28. A solar cell having integrated spherical or grain-shaped semiconductor elements, comprising:
an insulating support layer into which the spherical or grain-shaped semiconductor elements are incorporated, wherein the semiconductor elements protrude from the layer on at least one side of the support layer, and the semiconductor elements each comprising a spherical or grain-shaped substrate core that is coated at least with one conductive back contact layer and with one I-III-VI compound semiconductor layer;
a back contact layer on one side of the support layer, wherein a plurality of semiconductor elements on this side of the support layer have a surface that is free of I-III-VI compound semiconductors; and
a front contact layer on the side of the support layer on which the semiconductor elements do not have a surface that is free of I-III-VI compound semiconductors.

29. The solar cell according to claim 28, produced by a method comprising the steps of:
incorporating several spherical or grain-shaped semiconductor elements into an insulating support layer, wherein the semiconductor elements protrude from the surface of the support layer on at least one side of the support layer, and the semiconductor elements each comprise a spherical or grain-shaped substrate core that is coated at least with one conductive back contact layer and with one I-III-VI compound semiconductor layer;
removing parts of the semiconductor elements on one side of the support layer so that a surface of the conductive back contact layer of the semiconductor elements is exposed;
applying a back contact layer onto a side of the support layer on which parts of the semiconductor elements have been removed; and
applying a front contact layer onto the side of the support layer on which no semiconductor elements have been removed.

30. The solar cell according to claim 28, wherein the insulating support layer comprises a thermoplastic material.

31. The solar cell according to claim 28, wherein the support layer comprises a polymer selected from the group consisting of epoxides, polycarbonates, polyesters, polyurethanes, polyacrylics, and polyimides.

32. The solar cell according to claim 28, wherein the spherical or grain-shaped semiconductor elements are semiconductor elements, wherein the semiconductor element has a spherical or grain-shaped substrate core comprising soda-lime glass and coated at least with one back contact layer comprising molybdenum and one I-III-VI compound semiconductor.

33. The solar cell according to claim 28, wherein the semiconductor elements are coated with a I-III-VI compound semiconductor selected from the group consisting of copper indium diselenides, copper indium disulfides, copper indium gallium diselenides and copper indium gallium diselenide disulfides.

34. The solar cell according to claim 28, wherein the front contact layer comprises a conductive material.

35. The solar cell according to claim 34, wherein the front contact layer comprises a transparent conductive oxide (TCO).

36. The solar cell according to claim 28, wherein the back contact layer comprises a conductive material.

37. The solar cell according to claim 36, wherein the back contact layer comprises a metal, a transparent conductive oxide (TCO) or a polymer having conductive particles.

38. The solar cell according to claim 37, wherein the back contact layer comprises a polymer selected from the group consisting of epoxy resins, polyurethanes and/or polyimides having conductive particles selected from the group consisting of carbon, indium, nickel, molybdenum, iron, nickel chromium, silver, aluminum and corresponding alloys or oxides.

39. The solar cell according to claim 38, characterized in that wherein the back contact layer comprises an intrinsic conductive polymer.

40. A photovoltaic module, comprising at least one solar cell according to claim 28.

41. The semiconductor element according to claim 10, wherein the diameter of the substrate core is in the order of magnitude approximately 0.2 mm.
